(19) United States
(12) Patent Application Publication
(10) Pub. No.: US 2018/0224309 A1
(43) Pub. Date: Aug. 9, 2018

(54) A NUCLEAR MAGNETIC RESONANCE FLOWMETER AND A METHOD OF MEASURING FLOW USING NUCLEAR MAGNETIC RESONANCE

(71) Applicant: Gill Corporate Limited, New Milton (GB)

(72) Inventors: Robert Bacon, Hampshire (GB); Samuel William Birtwell, Hampshire (GB); Michael John Gill, Hampshire (GB); Oliver Stewart Blacklock, Hampshire (GB)

(21) Appl. No.: 15/749,320

(22) PCT Filed: Aug. 16, 2016
(86) PCT No.: PCT/EP2016/025088

§ 371 Date: Jan. 31, 2018

(30) Foreign Application Priority Data
Sep. 15, 2015 (GB) 1516324.9

(51) Int. Cl. G01F 1/716; G01R 33/44

(52) U.S. Cl. CPC G01F 1/716; G01V 3/14; G01R 33/448; G01R 33/445

(57) ABSTRACT

A nuclear magnetic resonance flowmeter comprising at least one coil (40) of electrically conductive material through which an electrical current flows when the apparatus is in use. This generates a magnetic field in a region through which flows a fluid the flow of which is to be measured and throughout which there is a uniform weak magnetic field such as the Earth's magnetic field. Electrical circuitry (46 to 52) is connected to the said at least one coil (40) to switch on and abruptly switch off such an electrical current. There is an NMR sensor (42) connected to the electrical circuitry (46 to 52) to provide a measure of the decay in the NMR signal from nuclei within such fluid following the abrupt switching off of such an electrical current. A processor (52) of the electrical circuitry (46 to 52) is formed and/or programmed to provide a measure of the flow of such fluid from the said measure of the decay. Also, a method of measuring the flow of a fluid using such a flowmeter.

The present invention relates to a nuclear magnetic resonance flowmeter and to a method of measuring flow using nuclear magnetic resonance.

One such flowmeter is described in U.S. Pat. No. 4,638,251. This describes apparatus for measuring the flow of non-homogeneous materials in an incompletely filled channel. The apparatus comprises a magnet forming the requisite magnetic field across the flow channel. The magnet co-operates with a coil providing an NMR output signal from selected species of subatomic particles in the material in the flow stream. A composition sensor coil inscribing a very small volume in selected portions of the flow channel is included to form an NMR output signal indicative of composition, the small volume being filled for that sensor. One problem with such a flowmeter is that it relies on a permanent magnet to generate the magnetic field required. This provides a problem with certain applications, for example in the case of measurement of the flow of water along a naturally formed river.

EP-A-0106472 describes a nuclear magnetic resonance method and apparatus in which a magnetic field is generated using coils through which are passed an electric current. However this method depends upon the creation of another magnetic field with a gradient. Whilst such an apparatus and method may be suitable for measuring the flow of fluid in a living body, they are less suitable for the measurement of flow for example in a naturally formed river.

WO-A-2009045670 describes a nuclear magnetic resonance method and apparatus for detection of a liquid under a surface, but this is a means of detection of static material rather than apparatus and a method for measuring flow.

The present invention seeks to address one or more of the foregoing shortcomings of such previously proposed nuclear magnetic resonance apparatus and methods.

Accordingly, the present invention is directed to a nuclear magnetic resonance flowmeter comprising at least one coil of electrically conductive material through which an electrical current flows when the apparatus is in use to generate a magnetic field in a region through which flows a fluid the flow of which is to be measured and throughout which there is a uniform weak magnetic field such as the Earth's magnetic field, electrical circuitry connected to the said at least one coil to switch on and abruptly switch off such an electrical current, there being an NMR sensor connected to the electrical circuitry to provide a measure of the decay in the NMR signal from nuclei within such fluid following the abrupt switching off of such an electrical current, and a processor of the electrical circuitry formed and/or programmed to provide a measure of the flow of such fluid from the said measure of the decay.

Although such apparatus is especially suitable for measuring the flow of water in a river, it could also be used to measure the flow of a fluid through a sewerage pipe especially if the latter is made of a non-magnetic material.

The said electrical current may be a direct current to generate a unidirectional magnetic field.

Alternatively, the said electrical current may be a pulsed or alternating current to generate a pulsed or alternating magnetic field.

The said NMR sensor may comprise the said at least one coil. This provides an economy of parts, and reduces the overall cost of production of the apparatus.

Alternatively, the said NMR sensor may comprise at least one other coil. The latter may be located in substantially the same position as the said at least one coil.

The coil or coils by means of which the magnetic field is generated may be sufficiently large to completely surround a river.

The present invention extends to a method of measuring the flow of a fluid, in which an electrical current is passed through at least one coil of electrically conductive material to generate a magnetic field in a region through which flows fluid the flow of which is to be measured and throughout which there is a uniform weak magnetic field such as the Earth's magnetic field, and an electrical current is made to pass through the said at least one coil and is abruptly switched off, whereupon an NMR sensor is used to provide a measure of the decay of the NMR signal from precessing nuclei within such fluid following the abrupt switching off of the electrical current, and a measure of the flow of such fluid from the said measure of the decay is provided using a processor of the electrical circuitry.

The NMR sensor may comprise the said at least one coil. Alternatively the NMR sensor may comprise at least one other coil.

The said at least one coil may surround a river the flow of water along which is to be measured.

Thus the foregoing method may be carried out using a flowmeter as described by one or more of the foregoing paragraphs setting out essential or optional features of the present invention.

Examples of a nuclear magnetic resonance flowmeter embodying the present invention, and examples of a method of measuring the flow of a fluid using a nuclear magnetic resonance flowmeter embodying the present invention, will now be described in greater detail with reference to the accompanying drawings, in which:

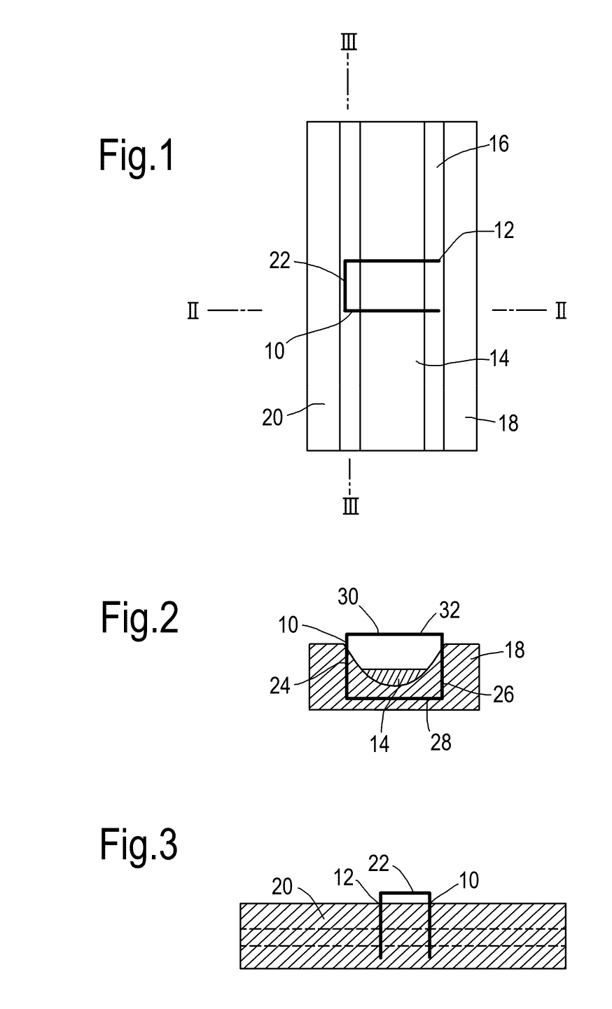

FIG. 1 shows an aerial diagrammatic view of a section of a river around which a part of apparatus made in accordance with the present invention is installed;

FIG. 2 shows a cross section of the river and the part of the apparatus shown in FIG. 1 in the plane indicated by the line II-II shown in FIG. 1;

FIG. 3 shows a longitudinal section of a river bank of the river shown in FIG. 1, and the part of the apparatus shown in FIG. 1, in the plane indicated by the line III-III in FIG. 1;

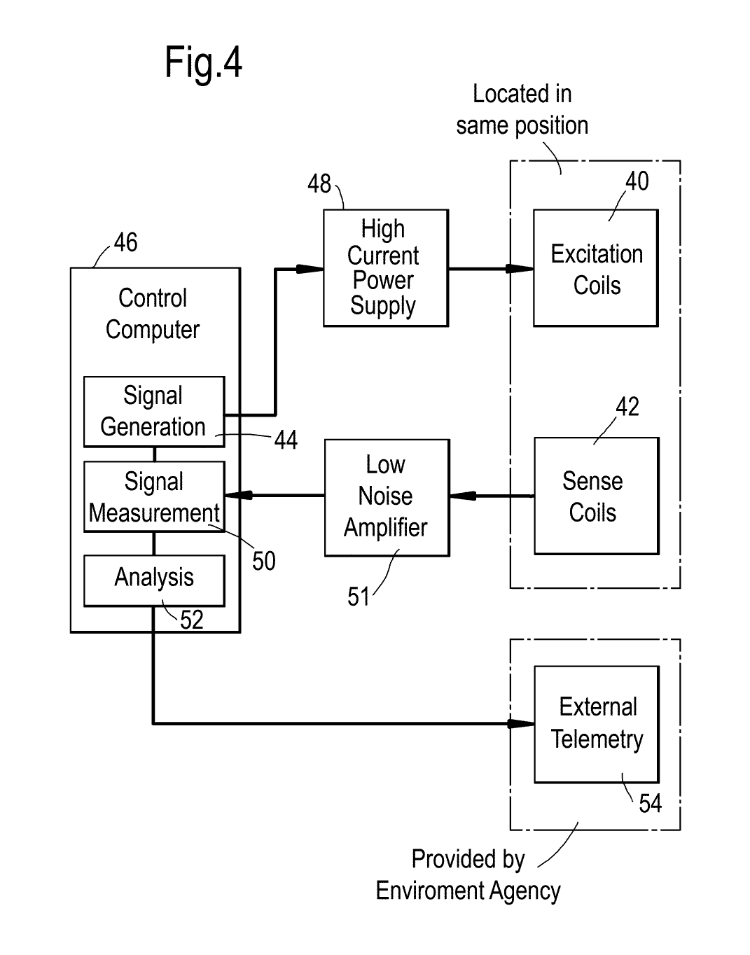

FIG. 4 shows electrical circuitry connected to that part of the apparatus shown in FIGS. 1 to 3;

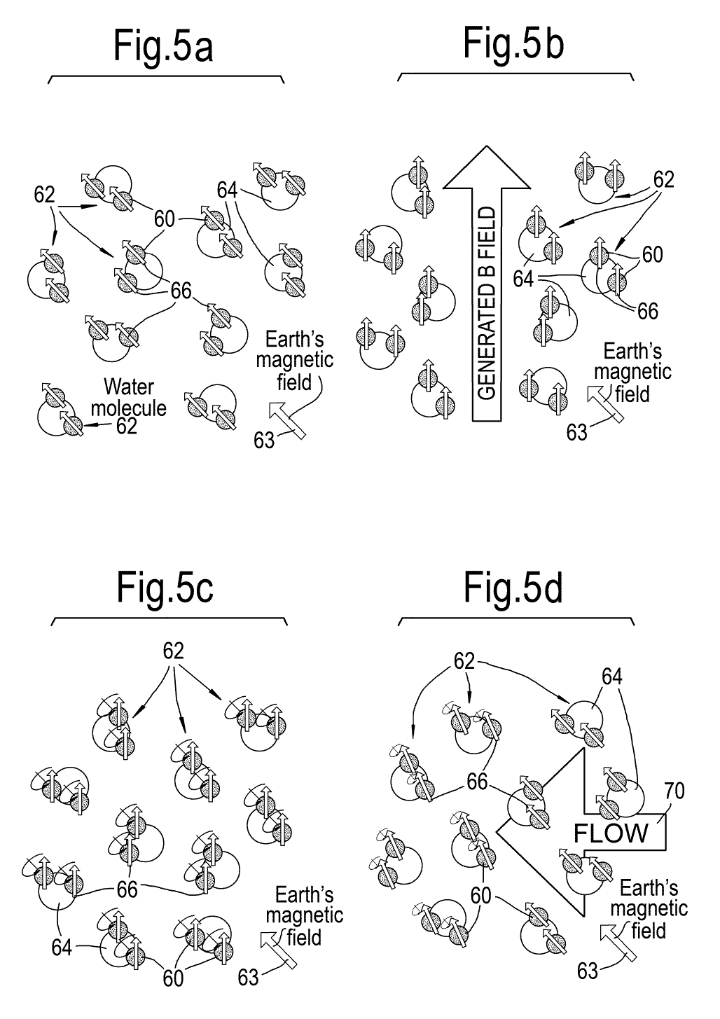

FIGS. 5a, 5b, 5C and 5d are explanatory diagrams;

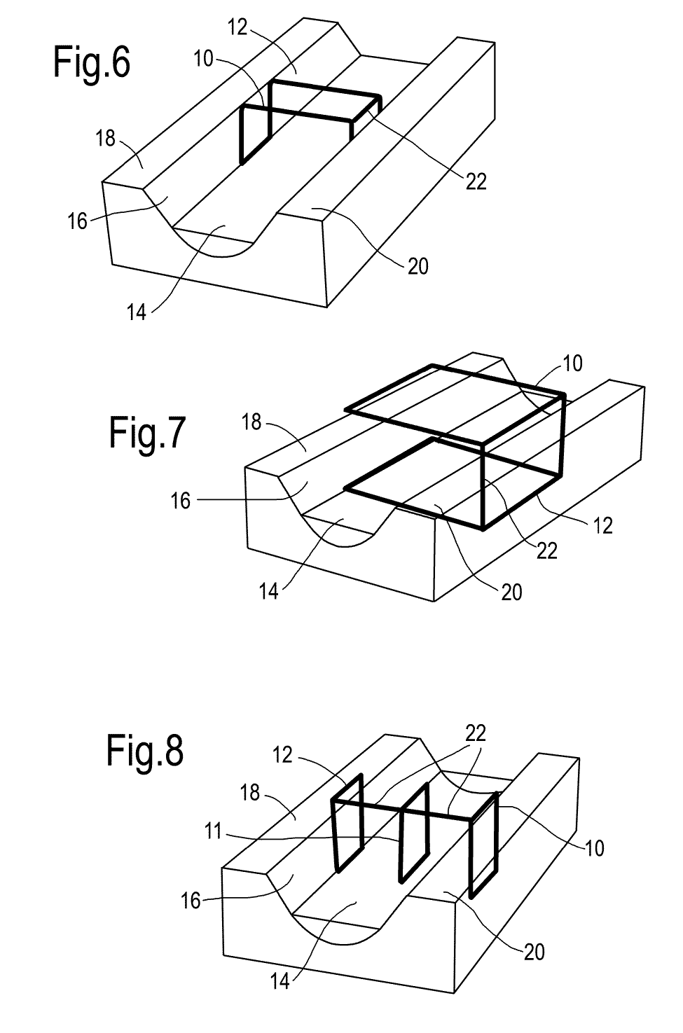

FIG. 6 shows a perspective view of the river and the part of the apparatus shown in FIG. 1;

FIGS. 7 and 8 show respective modifications to the part of the apparatus shown in FIG. 6; and

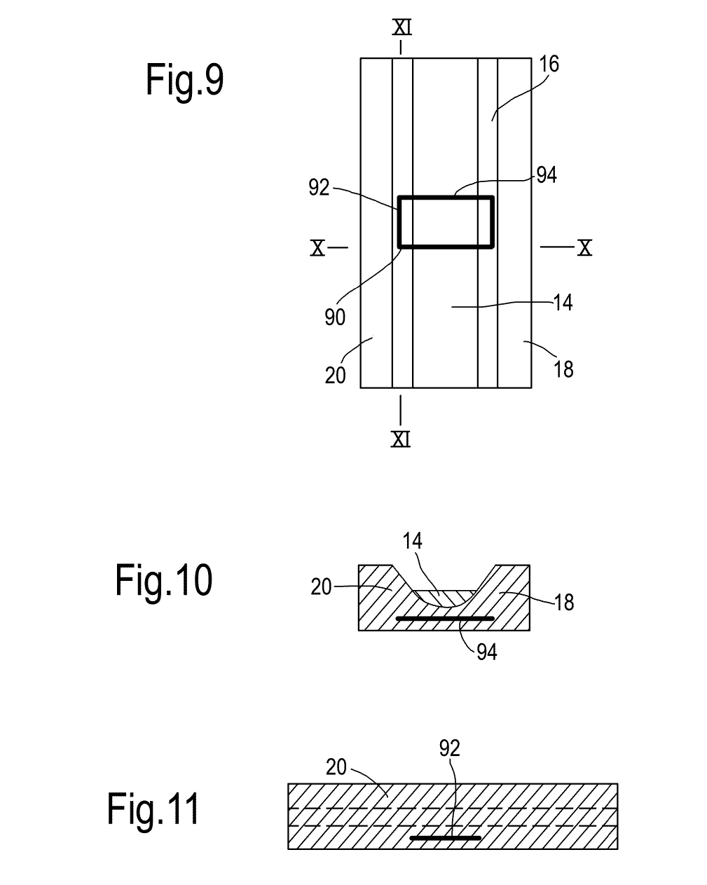

FIGS. 9 to 11 correspond to FIGS. 1 to 3 respectively and show in corresponding manner a modified construction of apparatus embodying the present invention.

Two rectangular plastics frames 10 and 12 are shown in FIGS. 1 to 3 both surrounding a river 14 which flows within a channel 16 defined between riverbanks 18 and 20. Each plastics frames 10 and 12 therefore extends transversely of the river 14. The two frames 10 and 12 are spaced apart and held together by a supporting strut 22, and are thereby located in substantially the same region of the river.

Each frame comprises two upright plastics tubes 24 and 26 respectively on opposite sides of the river 14, and two horizontal plastics tubes 28 and 30 connecting the lower ends and the upper ends of the upright tubes 24 and 26 respectively. The tubes 24, 26, 30 and 28 thereby create a continuous looped interior, providing a hard wearing housing for coils (not shown in FIGS. 1 to 3) which extend around the frame 10 within the interior thereof.

The frame 10 encloses excitation coils 40 (shown in FIG. 4 but not shown in FIGS. 1 to 3), and the frame 12 encloses sense coils 42 (also shown in FIG. 4 but not shown in FIGS. 1 to 3).

The excitation coils 40 are electrically connected to a signal generator 44 of a control processor or computer 46 via a high current power supply 48, and the sense coils 42 are connected to a signal measurement circuit 50 of the control computer 46 via a low noise amplifier 51.

The control computer 46 is also provided with an analysis unit 52 connected to an externally provided telemetry unit 54 provided by the environment agency of the territory within which flows the river 14.

The signal generator 44, the signal measurement circuit 50 and the analysis unit 52 of the control computer 46 are electrically interconnected.

The frames 10 and 12 together with the circuitry shown in FIG. 4 (apart from the telemetry unit 54) constitute a nuclear magnetic resonance flowmeter.

After a prolonged absence of any current flowing through the excitation coils 40, the nuclear magnetic moments of the hydrogen nuclei 60 of water molecules 62 in the river 14 in the region of the frames and 12 are oriented in alignment with the Earth's magnetic field 63 as indicated by the arrows 66 in FIG. 5a. In this regard it will be appreciated that the oxygen nuclei 64 of the water molecules 62 generally have a zero magnetic moment. The only naturally occurring oxygen nucleus that has a magnetic moment is ¹⁷O, and this is extremely rare.

When the circuitry shown in FIG. 4 commences its operating cycle, a signal is generated by the signal generator 44 to cause the high current power supply 48 to switch on, so that a high electrical current is passed through the excitation coils 40 for a short amount of time. Because the strong magnetic field 68 generated as a result is generally horizontal, more or less in alignment with the river 14, this strong magnetic field 68 is at an angle to the Earth's magnetic field. As a consequence, the magnetic moments of the hydrogen nuclei 60 are aligned in parallel with this strong magnetic field 68, as shown by the arrows 66 in FIG. 5b.

At this stage in the operating cycle of the circuitry shown in FIG. 4, the high current power supply 48 is abruptly switched off by the signal generator 44 of the computer 46. This in turn abruptly removes the strong magnetic field 68 from the region of water in the river 20 adjacent to the coils 10 and 12. Consequently, in this region, the magnetic moments of the hydrogen nuclei 66 begin to precess around the direction of the Earth's magnetic field, as shown by the curled arrows in FIG. 5c. Because of the uniformity of the Earth's magnetic field in the region concerned, all precession of the ¹H nuclei will be in phase. The frequency of this precession is the Larmour frequency for the ¹H nucleus within the Earth's magnetic field, being given by the equation:

ν=γB

in which ν is the Larmour frequency in MHz, γ is the gyromagnetic ratio of the ¹H nucleus in MHz/Tesla, and B is the strength of the Earth's magnetic filed in Tesla.

The precessing of the hydrogen nuclei decays, during a transitional phase in which the magnetic moments of the ¹H nuclei are realigned with the Earth's magnetic field, over a period of about two seconds. At the same time, within the region of the coils 10 and 12, the flow 70 of water in the river displaces precessing nuclei by ones which are not precessing because they have not been subject to the intense magnetic field 68 generated by the coil 10. Therefore, the oscillating magnetic field signal picked up by the sensor coils 42 and relayed to the computer 46 decays for two reasons: (i) because of the reduction in the energy with which the nuclei are precessing, and (ii) because of the flow of water in the river 14. The former can be determined experimentally and stored in the control computer, to be processed by the signal measurement circuit 50 by subtracting from it the signal received from the sensor coils 42, to provide a measure of the flow of water in the river 14 by means of the analysis unit 52 of the control computer 46. Since the coils 40 and 42 encompass the whole of the river channel in the region, the flow measurement is for the river as a whole. The output from the analysis unit 52 is relayed to the external telemetry 54. By means of repetition of the operating cycle of the circuit shown in FIG. 4, the external telemetry 54 is continually updated with the rate of flow of water along the river 14.

Numerous variations and modifications to the flowmeter illustrated in FIGS. 1 to 6 may occur to the reader without taking the resulting construction outside the scope of the present invention. For example, the coils 10 and 12 may be arranged in respective horizontal planes above and below the river 14, to generate a substantially vertical strong magnetic field, as shown in FIG. 7. Such a vertical magnetic field is therefore also at an angle to the Earth's magnetic field. Alternatively, the frames 10 and 12 may be replaced by three frames 10, 11 and 12, the frames being spaced apart from one another but being arranged parallel to one another and each extending in a direction which extends generally parallel to the river 14, one of the frames 12 being arranged in the bank 18, another 10 being arranged in the opposite bank 20, and a third 11 being located between those arranged in the banks of the river, centrally in relation to the river 14 itself, as shown in FIG. 8. As shown in FIGS. 9 to 11, the frames 10 and 12 shown in FIGS. 1 to 3 may be replaced by one single frame 90 of tubular plastics construction located generally horizontally underneath the river 14, of generally rectangular form having shorter sides 92 generally parallel to the flow of the river 14, and longer sides 94 generally transverse of the flow of the river 14, within which frame extends one or more coils 40/42 (shown in FIG. 4). Instead of the three frames 10, 11 and 12 shown in FIG. 8, the central one could be omitted, providing just the two frames 10 and 12, both of which are on or in the banks of the river but not in the river itself, so as not to disturb the flow thereof. Furthermore, one of the frames 10 and 12 could be omitted as well as the frame 11, so that the construction has only one frame 10 or 12 on or in a river bank, so that it does not disturb the flow of the river. In a further modification, there may be more than three frames 10, 11 and 12 parallel to one another and spaced apart across the river.

The benefit of the constructions shown in FIGS. 6, 7 and 9 to 11 is that no part of the flowmeter interferes with the flow of the river, or with its organic contents or with any wildlife in the river. Furthermore, the flowmeters shown in FIGS. 6, 7 and 9 to 11 will not be damaged by material being carried along by the river 14, nor by the water of the river itself. In this way the embodiments shown in FIGS. 6, 7 and 9 to 11 are non-intrusive.

Which of the embodiments of FIGS. 1 to 11 would be adopted in any given application would be the one to give the best relative values as regards costs and accuracy.

The sensor coil or coils 42 may be one of the same as the excitation coil or coils 40.

It will be appreciated that the electrical current passed through the excitation coil or coils 40 may be a direct current, to generate a unidirectional magnetic field, or it may be a pulsed or alternating current to generate a pulsed or alternating magnetic field, whether or not superimposed on a direct current to generate a pulsed or alternating magnetic field superimposed on a unidirectional magnetic field.

1. A nuclear magnetic resonance flowmeter comprising at least one coil of electrically conductive material through which an electrical current flows when the apparatus is in use to generate a magnetic field in a region through which flows a fluid the flow of which is to be measured and throughout which there is a uniform weak magnetic field such as the Earth's magnetic field, electrical circuitry connected to the said at least one coil to switch on and abruptly switch off such an electrical current, there being an NMR sensor connected to the electrical circuitry to provide a measure of the decay in the NMR signal from nuclei within such fluid following the abrupt switching off of such an electrical current, and a processor of the electrical circuitry formed and/or programmed to provide a measure of the flow of such fluid from the said measure of the decay.

2. A nuclear magnetic resonance flowmeter according to claim 1, in which the said electrical current is a direct current to generate a unidirectional magnetic field.

3. A nuclear magnetic resonance flowmeter according to claim 1, in which the said electrical current is a pulsed or alternating current to generate a pulsed or alternating magnetic field.

4. A nuclear magnetic resonance flowmeter according to claim 1, in which the said NMR sensor comprises the said at least one coil.

5. A nuclear magnetic resonance flowmeter according to claim 1, in which the said NMR sensor comprises at least one other coil.

6. A nuclear magnetic resonance flowmeter according to claim 5, in which the said at least one other coil is located in substantially the same position as the said at least one coil.

7. A nuclear magnetic resonance flowmeter according to claim 1, in which the coil or coils by means of which the magnetic field is generated are sufficiently large to completely surround a river.

8. A method of measuring the flow of a fluid, in which an electrical current is passed through at least one coil of electrically conductive material to generate a magnetic field in a region through which flows fluid the flow of which is to be measured and throughout which there is a uniform weak magnetic field such as the Earth's magnetic field, and an electrical current is made to pass through the said at least one coil and is abruptly switched off, whereupon an NMR sensor is used to provide a measure of the decay of the NMR signal from precessing nuclei within such fluid following the abrupt switching off of the electrical current, and a measure of the flow of such fluid from the said measure of the decay is provided using a processor of the electrical circuitry .

9. A method of measuring the flow of a fluid according to claim 8, using a flowmeter.

10. A method of measuring the flow of a fluid according to claim 9, in which the said at least one coil surrounds a river the flow of water along which is to be measured.
